(19) United States
(12) Patent Application Publication
(10) Pub. No.: US 2014/0246724 A1
(43) Pub. Date: Sep. 4, 2014

(54) MEMORY DEVICES

(71) Applicant: Samsung Electronics Co., Ltd., Suwon-Si (KR)

(72) Inventors: Sung-Ho JANG, Seoul (KR); Seung-Hun SON, Seoul (KR); Jung-Bun LEE, Ansan-si (KR)

(73) Assignee: SAMSUNG ELECTRONICS CO., LTD., Suwon-Si (KR)

(21) Appl. No.: 14/165,775

(22) Filed: Jan. 28, 2014

(30) Foreign Application Priority Data
Mar. 4, 2013 (KR) 10-2013-0023002

(51) Int. Cl. H01L 27/108

(52) U.S. Cl. CPC H01L 27/108
USPC 257/368

(57) ABSTRACT

Memory devices include a substrate including first to third regions, a memory element on the first region, a first transistor on the second region closer to the first region than to the third region and including a spacer filled with an insulating material, and a second transistor on the third region and including a spacer filled with air.

### CROSS-REFERENCE TO RELATED APPLICATION

This application claims priority from Korean Patent Application No. 10-2013-0023002 filed on Mar. 4, 2013 in the Korean Intellectual Property Office, and all the benefits accruing therefrom under 35 U.S.C. 119, the contents of which are incorporated herein by reference in their entirety.

### BACKGROUND

1. Technical Field

Example embodiments of the inventive concepts relate to memory devices.

2. Description of the Related Art

A semiconductor memory device is a memory device implemented using a semiconductor material, such as silicon (Si), germanium (Ge), gallium arsenide (GaAs), indium phosphide (InP), or the like. Semiconductor memory devices are largely classified by volatile memory devices and nonvolatile memory devices.

Volatile memory devices lose data when power supply is interrupted and may include a static random access memory (SRAM), a dynamic random access memory (DRAM), a synchronous dynamic random access memory (SDRAM), and so on.

Nonvolatile memory devices can retain data even when power supply is interrupted and may include a read only memory (ROM)), a programmable read only memory (PROM), an electrically programmable read only memory (EPROM), an electrically erasable and programmable read only memory (EEPROM), a flash memory device, a resistive memory device (e.g., a phase-change RAM (PRAM), a ferroelectric RAM (FRAM), a resistive RAM (RRAM) etc.), and so on.

As memory devices become more compact, it is an important to increase operating performance of transistors incorporated in the memory device for performing various functions.

### SUMMARY

Example embodiments of the inventive concepts relate to memory devices.

Example embodiments the inventive concepts provide a memory device having improved operating performance.

According to some example embodiments of the inventive concepts, there is provided a memory device, including a memory element on a substrate, and first and second transistors on the substrate. The first transistor includes a first source/drain, a first gate structure spaced apart from the first source/drain by a first distance, and a spacer on at least one side of the first gate structure and filled with an insulating material. The second transistor includes a second source/drain, a second gate structure spaced apart from the second source/drain by a second distance, and a spacer filled with air and on at least one side of the second gate structure. The second distance is different than the first distance.

The second distance may be greater than the first distance.

The memory device may further include a passivation layer preventing the first and second gate structures from being oxidized, and a first etch stopper layer on the spacer filled with the insulating material and the spacer filled with air. The passivation layer may be at one side of the spacer filled with air, and the first etch stopping layer may be at the other side of the spacer filled with air.

The passivation layer may contact the substrate.

The memory device may further include an insulation layer on the passivation layer and the first etch stopping layer. The spacer filled with air may be surrounded by the insulation layer.

The memory device may further include a second etch stopper layer contacting the substrate and on the one side of the spacer filled with air.

The memory device may further include an insulation layer on the passivation layer and the second etch stopper layer. The spacer filled with air may be surrounded by the insulation layer.

The first gate structure and the second gate structure may include a same material.

The first transistor may be on a core area having a sense amplifier configured to read data stored in the memory element, and the second transistor may be on a peripheral area having an input/output (I/O) circuit configured to output the data read by the sense amplifier to an area external to the memory device.

The memory element may include a dynamic random access memory (DRAM).

According to other example embodiments, there is provided a memory device, including a substrate including first to third regions, a memory element on the first region, a first transistor on the second region closer to the first region than to the third region and including a spacer filled with an insulating material, and a second transistor on the third region and including a spacer filled with air.

The first region may include a memory cell array area, the second region may include a core area, and the third region may include a peripheral area.

The memory cell array area may include a DRAM element, the core area may include a sense amplifier configured to read data stored in the DRAM element, and the peripheral area may include an input/output (I/O) circuit configured to output the data read by the sense amplifier to the outside.

The first transistor may further include a first source/drain and a first gate structure apart from the first source/drain by a first distance, and the second transistor may include a second source/drain and a second gate structure apart from the second source/drain by a second distance.

The second distance may be greater than the first distance.

According to still other example embodiments, a nonvolatile memory device, including a memory element in a memory cell region of a substrate, a first transistor in a core region of the substrate and including a first gate structure having first sidewalls each respectively insulated by an insulative material, and a second transistor in a peripheral region of the substrate and including a second gate structure having second sidewalls each respectively insulated by a cavity filled with air. The core region is closer to the memory cell region than the peripheral region is to the memory cell region.

The insulative material may be in the form of a spacer, and the cavity filled with air may be defined by an etch stop layer and a passivation layer.

The first transistor may be over a first source/drain region, and the first gate structure may be spaced apart from the first source/drain region by a first distance equal to or less than a width of the spacer. The second transistor may be over a second source/drain region, and the second gate structure may be spaced apart from the second source/drain region by a second distance greater than a width of the cavity.

The second distance may be greater than the first distance.

The insulative material may be in the form of a spacer, and the cavity filled with air may be defined by an insulation layer, an etch stop layer and a passivation layer.

### BRIEF DESCRIPTION OF THE DRAWINGS

Example embodiments will be more clearly understood from the following detailed description taken in conjunction with the accompanying drawings. FIGS. 1-18 represent non-limiting, example embodiments as described herein.

FIG. 1 is a partial layout view of a memory device according to some example embodiments of the inventive concepts;

FIG. 2 is a block diagram of the memory device shown in FIG. 1;

FIG. 3 is a cross-sectional view of the memory device shown in FIG. 1;

FIG. 4 is a cross-sectional view of a memory device according to other example embodiments of the inventive concepts;

FIG. 5 is a cross-sectional view of a memory device according to yet other example embodiments of the inventive concepts;

FIG. 6 is a cross-sectional view of a memory device according to still other example embodiments of the inventive concepts;

FIGS. 7 to 11 illustrate intermediate process steps for explaining a method for fabricating a memory device according to some example embodiments of the inventive concepts;

FIG. 12 illustrates an intermediate process step for explaining a method for fabricating a memory device according to other example embodiments of the inventive concepts;

FIGS. 13 and 14 illustrate intermediate process steps for explaining a method for fabricating a memory device according to still other example embodiments of the inventive concepts;

FIG. 15 is a block diagram of an electronic system to which memory devices according to example embodiments of the inventive concepts can be employed;

FIG. 16 illustrates an example electronic system used for a smart phone;

FIG. 17 illustrates an example electronic system used for a tablet PC; and

FIG. 18 illustrates an application example in which the electronic system shown in FIG. 15 is applied to a notebook computer.

### DETAILED DESCRIPTION OF EXAMPLE EMBODIMENTS

Various example embodiments will now be described more fully with reference to the accompanying drawings in which some example embodiments are shown. However, specific structural and functional details disclosed herein are merely representative for purposes of describing example embodiments. Thus, the invention may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope.

In the drawings, the thicknesses of layers and regions may be exaggerated for clarity, and like numbers refer to like elements throughout the description of the figures.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that, if an element is referred to as being “connected” or “coupled” to another element, it can be directly connected, or coupled, to the other element or intervening elements may be present. In contrast, if an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof.

Spatially relative terms (e.g., “beneath,” “below,” “lower,” “above,” “upper” and the like) may be used herein for ease of description to describe one element or a relationship between a feature and another element or feature as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various features will be described in detail with reference to the attached drawings. However, example embodiments described are not limited thereto.

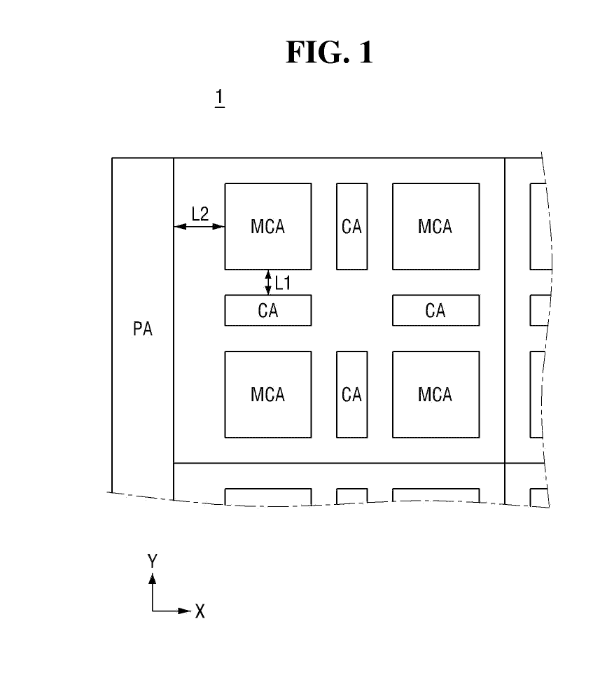

Hereinafter, a memory device according to example embodiments of the inventive concepts will be described with reference to FIGS. 1 to 3.

FIG. 1 is a partial layout view of a memory device according to some example embodiments of the inventive concepts.

In the following description, the memory device according to example embodiment of the inventive concepts will be described with regard to a dynamic random access memory (DRAM) by way of example, but the inventive concepts are not limited thereto.

Referring to FIG. 1, a memory device 1 includes a memory cell array area (MCA), a core area (CA) and a peripheral area (PA) formed on a substrate.

Memory elements, for example, may be disposed on the MCA. In particular, in some example embodiments of the inventive concepts, a DRAM element, for example, may be disposed on the MCA. Meanwhile, in the memory device 1 according to the example embodiments of the inventive concepts, the MCA may include a plurality MCAs repeatedly disposed, as shown in FIG. 1.

The CA is disposed to be close to the MCA, and circuits used to read or write data from/to the memory element disposed on the MCA may be disposed on the CA. For example, the CA may be disposed to be adjacent to the MCA in a first direction (X) and a second direction (Y), as shown in FIG. 1.

Circuits required for the memory device 1 to communicate with an external device or to process externally applied signals to be used by the memory device 1 may be disposed on the PA. As shown in FIG. 1, the PA may be disposed on the periphery of the memory device 1.

Meanwhile, a first length L1 ranging from the CA to the MCA and a second length L2 ranging from the PA to the MCA may be different from each other. In some example embodiments of the inventive concepts, the first length L1 may be smaller than the second length L2, as shown. In other words, the CA may be disposed to be closer to the MCA than to the PA. In some example embodiments of the inventive concepts, the first length L1 may be 0. That is to say, the CA and the MCA may be disposed to contact each other.

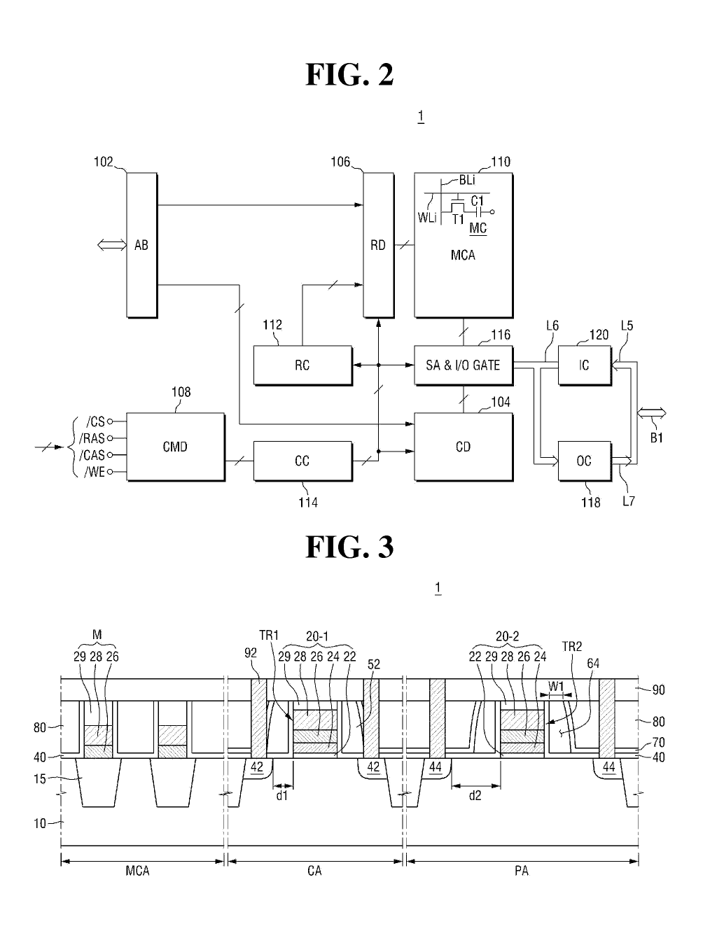

FIG. 2 is a block diagram of the memory device shown in FIG. 1.

Referring to FIG. 2, the memory device 1 includes an address buffer 102, a command decoder 108, a refresh circuit 112, a control circuit 114, a row decoder 106, a column decoder 104, a sense amplifier (AMP) & I/O gate 116, a memory cell array 110, an input circuit 120, and an output circuit 118.

In a case of a DRAM, the memory cell array 110 may be in a matrix configuration having unit memory cells MCs connected to interconnections of rows and columns, each of the unit memory cells MCs consisting of an access transistor T1 and a storage capacitor C1. Here, the rows may correspond to word lines WLi, and the columns may correspond to bit lines BLi. Meanwhile, the memory cell array 110 may include, but not limited to, four memory banks, and each bank may have a memory capacity of, for example, 64 Mb, 128 Mb, 256 Mb, 512 Mb, or 1024 Mb.

In order to read the data stored in a memory cell MC through a data bus B1, a row address is first received through the address buffer 102 and a word line WLi is selected by the row decoder 106 performing decoding. Next, if the word line WLi is selected, charges stored in the memory cells MCs belonging to the same word line are developed to a corresponding bit line BLi by a charge sharing method, and are amplified by each bit line sense AMP (not shown).

Meanwhile, a column address is received through the address buffer 102 and a column select line is selected by the column decoder 104 performing decoding. Accordingly, the output of the bit line sense AMP corresponding to the column select line is transferred to local I/O line through the column select line.

The sense AMP & I/O gate 116, connected to a global I/O line, further amplifies and gates the data whose level is slightly weakened as the data is transmitted through a data transfer route. The read data output from the sense AMP & I/O gate 116 is applied to the output circuit 118 through a line L6. The output circuit 118 supplies data of 8, 16, 32, or 64 bits set according to the data output timing to the data bus B1 through a line L7. Accordingly, the data read from the memory cell MC is output to the outside.

During a refresh operation performed by the refresh circuit 112, data is read from a memory cell MC within a data retention period of the memory cell MC, the data read from the corresponding memory cell MC is written back to the corresponding memory cell MC without a data output operation through the output circuit 118.

The refresh operation, the data read operation and the data write operation may be selectively performed by the operations performed by the command decoder 108 and the control circuit 114. The command decoder 108 receives a chip select signal (/CS), a row address strobe signal /RAS, a column address strobe signal (/CAS), and a write enable signal (/WE) and interprets commands. The control circuit 114 receives the output of the command decoder 108 and outputs various control signals and timing signals required for the refresh circuit 112, the row decoder 106, the column decoder 104, the sense AMP & I/O gate 116, and other circuit blocks.

During the data write operation, write data is applied to the input circuit 120 through the data bus B1 and the line L5. The write data applied through the input circuit 120 is sequentially written to the memory cell MC selected by the row decoder 106 and the column decoder 104 via the line L6 through the sense AMP & I/O gate 116.

For example, the output circuit 118 and the input circuit 120 may constitute an I/O circuit, which is disposed on the peripheral area (PA of FIG. 1). Although not shown in detail, a delay locked loop (DLL) circuit (not shown) and an electrostatic discharge (ESD) circuit (not shown) may further be disposed on the peripheral area (PA of FIG. 1).

The memory cell array 110 may be disposed on the memory cell array area (MCA of FIG. 1). The column decoder 104, the row decoder 106, and the sense AMP & I/O gate 116 may be formed on the core area (CA of FIG. 1). Therefore, the column decoder 104, the row decoder 106 and the sense AMP & I/O gate 116 may be disposed to be closer to the memory cell array 110 than to the output circuit 118 and the input circuit 120.

FIG. 3 is a cross-sectional view of the memory device shown in FIG. 1.

Referring to FIG. 3, the memory device 1 includes a memory element M, and first and second transistors TR1 and TR2, disposed on the MCA, CA and PA, respectively, of the substrate 10.

The substrate 10 may be made of one or more semiconductor materials selected from the group consisting of Si, Ge, SiGe, GaP, GaAs, SiC, SiGeC, InAs and InP. In some example embodiments of the inventive concepts, the substrate 10 may include silicon on insulator (SOI). An isolation layer 15 may be formed in the substrate 10 by, for example, shallow trench isolation (STI) to isolate the memory element M and the first and second transistors TR1 and TR2 from each other.

The memory element M may be formed on the MCA of the substrate 10. In the present example embodiments, the memory element M may be, for example, a DRAM element, but the inventive concepts are not limited thereto.

The memory element M may include a barrier layer 26, a metal layer 28, and a capping layer 29 sequentially stacked one on another. The barrier layer 26 may prevent a metal of the metal layer 28 from being diffused into the substrate 10. In some example embodiments of the inventive concepts, the barrier layer 26 includes TiN and the metal layer 28 may include W, but not limited thereto. The capping layer 29 may include, for example, SiN, but the inventive concepts are not limited thereto.

The first and second transistors TR1 and TR2 may be disposed on the CA and PA of the substrate 10. The first transistor TR1 disposed on the CA of the substrate 10 may include a first gate structure 20-1, a spacer 52 filled with an insulating material, and a first source/drain 42.

The first gate structure 20-1 may include a gate insulation layer 22, a polygate layer 24, a barrier layer 26, a metal layer 28, and a capping layer 29 sequentially stacked one on another. In some example embodiments of the inventive concepts, the gate insulation layer 22 may include, for example, SiO₂. In other example embodiments, the gate insulation layer 22 may include, for example, a high-k material. In detail, the gate insulation layer 22 may include, for example, a material selected from the group consisting of HfO₂, ZrO₂, Ta₂O₅, TiO₂, SrTiO₃, BaTiO₃, and SrTiO₃. The gate insulation layer 22 may be formed to an appropriate thickness according to the kind of device to be formed. The polygate layer 24 may include, for example, polysilicon (p-si), but the inventive concepts are not limited thereto.

As shown, the spacer 52 filled with an insulating material may be disposed at opposite sides of the first gate structure 20-1. The insulating material filling the spacer 52 may include, for example, SiO₂, but the inventive concepts are not limited thereto.

The first source/drain 42 may be disposed in the substrate 10 positioned at opposite sides of the first gate structure 20-1. Although not specifically illustrated, a lightly doped drain (LDD) may further be disposed in the substrate 10 positioned at opposite sides of the first gate structure 20-1. A contact 92 making contact with the first source/drain 42 while passing through the first and second interlayer insulation layers 80 and 90 may be disposed on the first source/drain 42.

The second transistor TR2 disposed on the PA of the substrate 10 may include a second gate structure 20-2, an airgap spacer 64 and a second source/drain 44.

As shown, the second gate structure 20-2 may be configured in substantially the same as the first gate structure 20-1.

The airgap spacer 64 may be formed (or, defined) by the passivation layer 40, the first etch stopping layer 70 and the second interlayer insulation layer 90, as shown. In detail, the passivation layer 40 may be disposed at one side and bottom side of the airgap spacer 64, the first etch stopping layer 70 may be disposed at the other side of the airgap spacer 64, and the second interlayer insulation layer 90 may be disposed on a top portion of the airgap spacer 64.

The passivation layer 40 disposed at opposite sides of the memory element M and the first and second gate structures 20-1 and 20-2 may prevent the memory element M, the barrier layer 26 included in the first and second gate structures 20-1 and 20-2 and the metal layer 28 from being exposed to the outside and oxidized. The passivation layer 40 may include, for example, SiN, SiBN, SiON or SiO₂, but the inventive concepts are not limited thereto. Meanwhile, in the illustrated example embodiments, the passivation layer 40 may be disposed to extend along a top surface of the substrate 10. That is to say, the passivation layer 40 may be disposed to make contact with the top surface of the substrate 10.

The first etch stopping layer 70 may be disposed on the passivation layer 40, the spacer 52 filled with an insulating material and the airgap spacer 64. In addition, the second interlayer insulation layer 90 disposed on the first interlayer insulation layer 80 having a planarized top surface may cover the top portion of the airgap spacer 64. In detail, the second interlayer insulation layer 90 may cover the top portion of the airgap spacer 64 such that a width of the top portion of the airgap spacer 64 becomes a first width W1.

The second source/drain 44 may be disposed in the substrate 10 positioned at the opposite sides of the second gate structure 20-2. Although not specifically illustrated, a lightly doped drain (LDD) may further be disposed in the substrate 10 positioned at opposite sides of the second gate structure 20-2. A contact 92 making contact with the second source/drain 44 while passing through the first and second interlayer insulation layers 80 and 90 may be disposed on the second source/drain 44.

In the present example embodiments, the first transistor TR1 disposed on the CA of the substrate 10 may be a transistor forming one of elements disposed on the CA (for example, the column decoder 104, the row decoder 106, and the sense AMP & I/O gate 116 shown in FIG. 2). That is to say, in some example embodiments of the inventive concepts, the first transistor TR1 may be a transistor forming a sense amplifier (116 of FIG. 2) for reading the data stored in the memory element M.

Meanwhile, the second transistor TR2 disposed on the PA of the substrate 10 may be a transistor forming one of elements disposed on the PA (for example, the output circuit 118 and the input circuit 120 shown in FIG. 2). That is to say, in some example embodiments of the inventive concepts, the second transistor TR2 may be a transistor forming an output circuit (118 of FIG. 2) for outputting the data read through the sense amplifier (116 of FIG. 2) to the outside, or an input circuit (120 of FIG. 2).

As described above, because the CA is disposed to be adjacent to the MCA, a space of the CA may be smaller than that of the PA. Therefore, as shown, a first distance d1 between the first gate structure 20-1 and the first source/drain 42 may be different from a second distance d2 between the second gate structure 20-2 and the second source/drain 44. In detail, the second distance d2 may be greater than the first distance d1.

As the size of the memory device 1 gradually shrinks, the operating performance of each of the first and second transistors TR1 and TR2 is greatly affected by parasitic capacitance between the first gate structure 20-1 and the first source/drain 42 and parasitic capacitance between the second gate structure 20-2 and the second source/drain 44. In detail, as the memory device 1 is gradually becoming smaller and smaller, the parasitic capacitance between the first gate structure 20-1 and the first source/drain 42 and the parasitic capacitance between the second gate structure 20-2 and the second source/drain 44 gradually increase, lowering the performance of each of the first and second transistors TR1 and TR2.

Therefore, in the present example embodiments, because the distance d2 between the second gate structure 20-2 and the second source/drain 44 is relatively large, the airgap spacer 64 with an airgap easily formed is formed for the second transistor TR2, thereby improving the operating performance of the second transistor TR2. As described above, because the second transistor TR2 is widely used as a transistor constituting circuits associated with the operating speed of the memory device 1 (for example, I/O circuit, DLL circuit, etc.), improvement in the operating performance of the second transistor TR2 may improve the overall operating speed of the memory device 1.

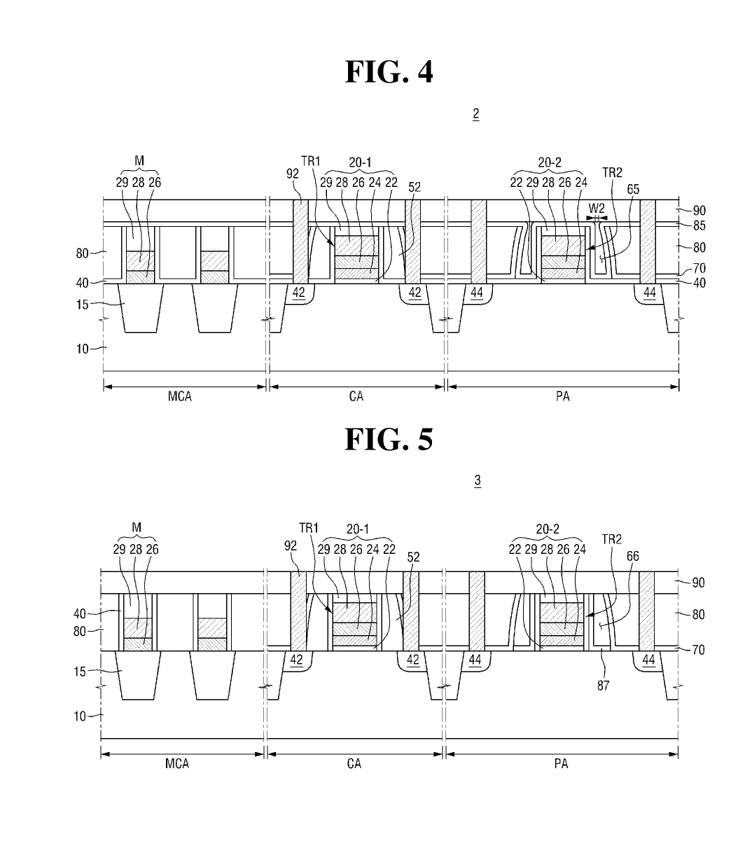

FIG. 4 is a cross-sectional view of a memory device according to other example embodiments of the inventive concepts.

Hereinafter, substantially the same contents as those of the previous example embodiments may be omitted and the following description will focus on differences between the present and previous example embodiments.

Referring to FIG. 4, a memory device 2 according to example embodiments of the inventive concepts may further include a second insulation layer 85 disposed between a first interlayer insulation layer 80 and a second interlayer insulation layer 90. As shown in FIG. 4, the second insulation layer 85 extends along a top surface of the first interlayer insulation layer 80 to then be disposed within an airgap spacer 65. That is to say, in the present example embodiments, the second insulation layer 85 may also be disposed on a passivation layer 40 and a first etch stopping layer 70. Accordingly, the airgap spacer 65 may be formed such that it is surrounded by the second insulation layer 85, as shown in FIG. 4.

A top surface of the airgap spacer 65 may have a second width W2. Here, the second width W2 may be smaller than a first width (W1 of FIG. 3) of the airgap spacer (64 of FIG. 3). As will be described later, the second interlayer insulation layer 90 may be formed on the first interlayer insulation layer 80 to form the airgap spacer 64 (or 65 of FIG. 4) by a method which has poor step coverage. When the second interlayer insulation layer 90 is formed in such a manner, the smaller the upper width of the airgap W1 (or W2 of FIG. 4), the less the possibility of the second interlayer insulation layer 90 penetrating into the airgap, thereby forming the airgap more efficiently.

Therefore, in the present example, the second insulation layer 85 is further formed, as shown in FIG. 4, compared to the previous example embodiments, thereby ensuring higher reliability in forming the airgap spacer 65 than in forming the airgap spacer (64 of FIG. 3) in the previous example embodiments.

FIG. 5 is a cross-sectional view of a memory device according to yet other example embodiments of the inventive concepts.

Hereinafter, substantially the same contents as those of the previous example embodiments may omitted and the following description will focus on differences between the present and previous example embodiments.

Referring to FIG. 5, in a memory device 3 according to example embodiments of the inventive concepts, a second etch stopper layer 87 may further be disposed at one side of a passivation layer 40. As shown in FIG. 5, the second etch stopper layer 87 may be disposed to extend along one side surface of the second gate structure 20-2 and a top surface of a substrate 10. As will be described later, the second etch stopper layer 87 may protect a second source/drain 44 in the course of fabricating the memory device 3 according to the example embodiments of the inventive concepts.

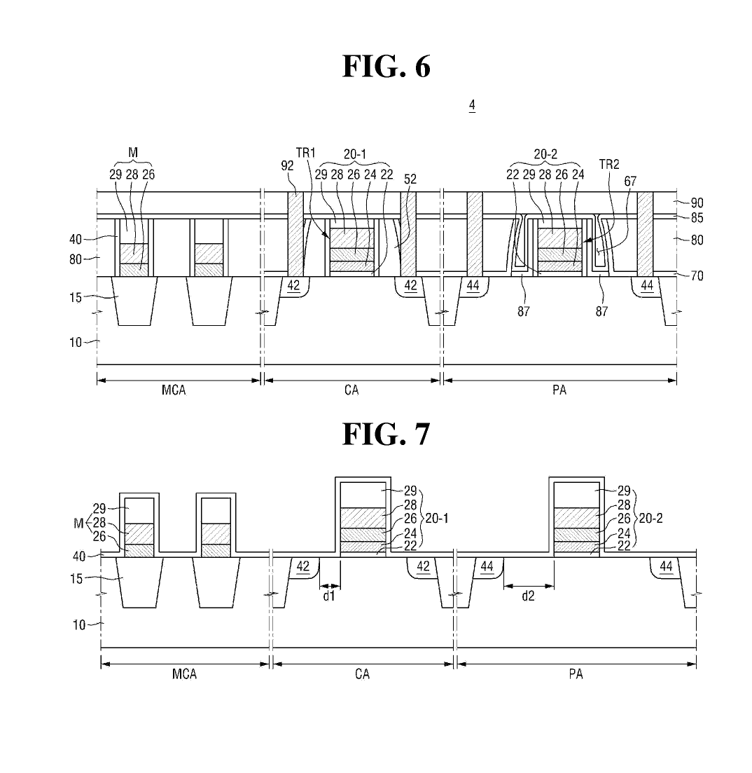

FIG. 6 is a cross-sectional view of a memory device according to still another embodiment of the inventive concepts. Hereinafter, substantially the same contents as those of the previous example embodiments may be omitted and the following description will focus on differences between the present and previous example embodiments.

Referring to FIG. 6, in a memory device 4 according to example embodiments of the inventive concepts, a second insulation layer 85 may further be provided, compared to the memory device (3 of FIG. 5) according to the previous example embodiments. Accordingly, the airgap spacer 67 may be formed to be surrounded by the second insulation layer 85, as shown in FIG. 6.

The presence of the second insulation layer 85 may further improve the reliability in forming the airgap spacer 67 than in forming the airgap spacer (66 of FIG. 5) in the previous example embodiments, which is substantially the same as described above and a repeated explanation thereof will be omitted.

Next, a method for fabricating a memory device according to example embodiments of the inventive concepts will be described with reference to FIGS. 3 and 7 to 11.

FIGS. 7 to 11 illustrate intermediate process steps for explaining a method for fabricating a memory device according to some example embodiments of the inventive concepts.

First, referring to FIG. 7, a memory element M, a first gate structure 20-1, and a second gate structure 20-2 are formed on a substrate 10.

In detail, an isolation layer 15 is first formed in the substrate 10. Here, the substrate 10 may be made of one or more semiconductor materials selected from the group consisting of Si, Ge, SiGe, GaP, GaAs, SiC, SiGeC, InAs and InP. In some example embodiments of the inventive concepts, the substrate 10 may include silicon on insulator (SOI). An isolation layer 15 may be formed in the substrate 10 by, for example, shallow trench isolation (STI), but the inventive concepts are not limited thereto.

Next, a gate insulation layer 22 and a polygate layer 24 are sequentially stacked on a core area (CA) and a peripheral area (PA). As shown, the gate insulation layer 22 and the polygate layer 24 may not be formed on a memory cell array area (MCA).

In some example embodiments of the inventive concepts, the gate insulation layer 22 may include, for example, SiO₂. In other example embodiments, the gate insulation layer 22 may include, for example, a high-k material. In detail, the gate insulation layer 22 may include, for example, a material selected from the group consisting of HfO₂, ZrO₂, Ta₂O₅, TiO₂, SrTiO₃, BaTiO₃, and SrTiO₃. The gate insulation layer 22 may be formed to an appropriate thickness according to the kind of device to be formed. The polygate layer 24 may include, for example, polysilicon (p-si), but the inventive concepts are not limited thereto.

Next, a barrier layer 26, a metal layer 28, and a capping layer 29 are sequentially stacked on the MCA, the CA and the PA.

The barrier layer 26 may prevent a metal of the metal layer 28 from being diffused into the substrate 10. In some example embodiments of the inventive concepts, the barrier layer 26 includes TiN and the metal layer 28 may include W, but not limited thereto. The capping layer 29 may include, for example, SiN, but the inventive concepts are not limited thereto.

Next, the layers stacked on the MCA, CA and PA are patterned, to form a memory element M, a first gate structure 20-1 and a second gate structure 20-2. In detail, the barrier layer 26, the metal layer 28, and the capping layer 29, stacked on the MCA, are patterned to form the memory element M shown in FIG. 7, and the gate insulation layer 22, the polygate layer 24, the polygate layer 24, the barrier layer 26, the metal layer 28, and the capping layer 29, stacked on the CA and PA, are patterned to form the first and second gate structures 20-1 and 20-2 shown in FIG. 7.

Next, a passivation layer 40 is formed on the MCA, CA and PA. The passivation layer 40 is formed to cover the memory element M, the first gate structure 20-1 and the second gate structure 20-2, thereby preventing the barrier layer 26 and the metal layer 28 included in the memory element M, the first gate structure 20-1 and the second gate structure 20-2 from being exposed to the outside and oxidized. The passivation layer 40 may include, for example, SiN, SiBN, SiON or SiO₂, but the inventive concepts are not limited thereto.

Next, as shown in FIG. 7, first and second source/drain 42 and 44 are formed at opposite sides of the first gate structure 20-1 and the second gate structure 20-2. In detail, the first source/drain 42 is formed at opposite sides of the first gate structure 20-1 to be a first distance d1 apart from the first gate structure 20-1, and the second source/drain 44 is formed at opposite sides of the second gate structure 20-2 to be a second distance d2 apart from second gate structure 20-2. In some example embodiments of the inventive concepts, the first distance d1 and the second distance d2 may be different from each other. In detail, as shown in FIG. 7, the second distance d2 may be greater than the first distance d1.

Meanwhile, the first and second source/drain 42 and 44 are formed by, for example, an implantation process. That is to say, in the present example embodiments, impurity may be transmitted through the passivation layer 40 through the implantation process to then be injected into the substrate 10. In addition, although not specifically illustrated, after the implantation process for forming the first and second source/drain 42 and 44, a separate implantation process for forming a lightly doped drain (LDD) may further be performed.

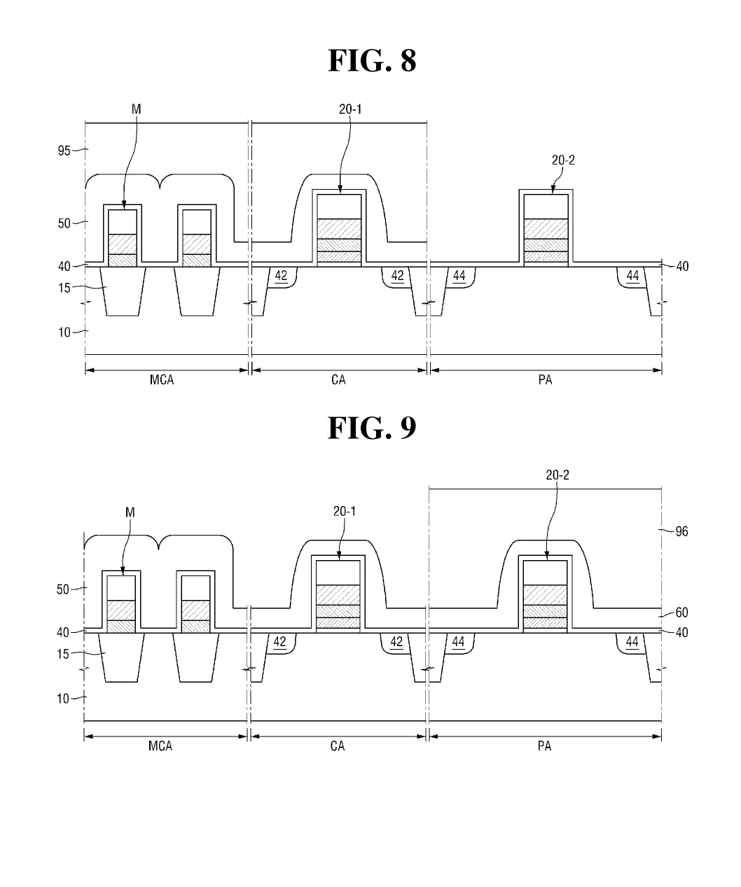

Next, referring to FIG. 8, a first insulation layer 50 is formed on the MCA, CA and PA. Here, the first insulation layer 50 may include, for example, SiO₂, but the inventive concepts are not limited thereto.

Next, a first mask 95 selectively masking only the MCA and the CA is formed on the first insulation layer 50. In addition, the first insulation layer 50 on the PA exposed by the first mask 95 may be removed by, for example, wet etching.

Next, referring to FIG. 9, a sacrificial layer 60 is formed on the MCA, CA and PA. In some example embodiments of the inventive concepts, the sacrificial layer 60 may include a different material from the first insulation layer 50. In addition, in some example embodiments of the inventive concepts, the second gate structure 20-2 and the sacrificial layer 60 may include the same material. In detail, the polygate layer 24 and the sacrificial layer 60 included in the second gate structure 20-2 may include the same material, for example, polysilicon (p-si), but the inventive concepts are not limited thereto.

Subsequently, a second mask 96 selectively masking only the peripheral area (PA) is formed on the sacrificial layer 60. Then, the sacrificial layer 60 on the MCA and CA exposed by the second mask 96 is removed by, for example, wet etching. When the sacrificial layer 60 on the MCA and CA is removed, etching selectivity of the wet etching process may be adjust to prevent the first insulation layer 50 underlying the sacrificial layer 60 from being damaged.

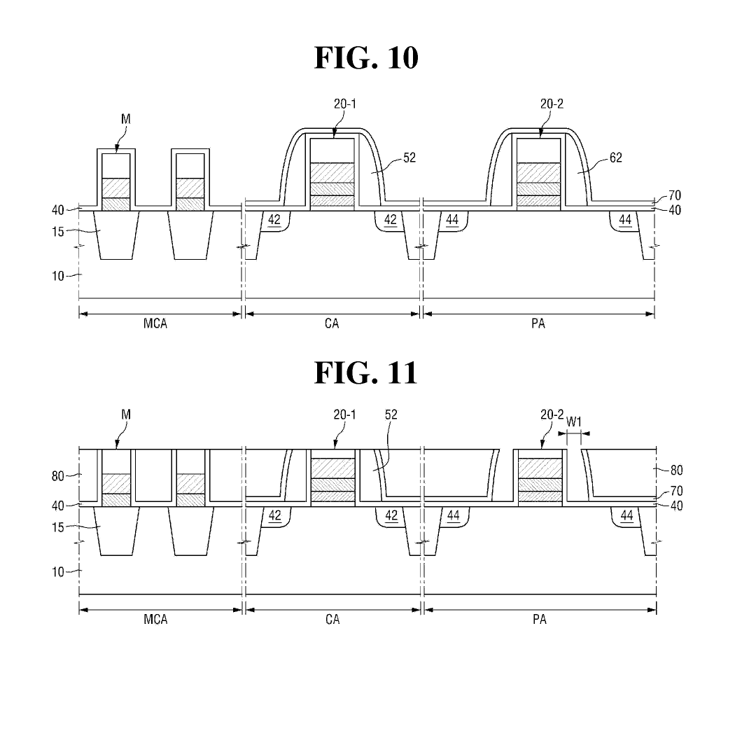

Next, referring to FIG. 10, the first insulation layer (50 of FIG. 9) formed on the MCA and CA and a portion of the sacrificial layer (60 of FIG. 9) formed on the PA are removed by, for example, wet etching or dry etching. In detail, the first insulation layer (50 of FIG. 9) formed to be adjacent to the memory element M is completely removed, and the first insulation layer (50 of FIG. 9) formed to be adjacent to the first gate structure 20-1 is partially removed to form a first spacer 52, as shown in FIG. 10. In addition, a portion of the sacrificial layer (60 of FIG. 9) formed to be adjacent to the second gate structure 20-2 is removed to form a second spacer 62.

Subsequently, a first etch stopping layer 70 is formed on the MCA, CA and PA. In addition, a third mask (not shown) selectively masking only the CA and PA is formed on the first etch stopping layer 70. The first etch stopping layer 70 on the MCA exposed by the third mask is removed by, for example, wet etching or dry etching.

Next, referring to FIG. 11, a first interlayer insulation layer 80 is formed on the MCA, CA and PA. Here, the first interlayer insulation layer 80 may be formed to sufficiently cover the first spacer 52 and the second spacer (62 of FIG. 10). In some example embodiments of the inventive concepts, the first interlayer insulation layer 80 may include, for example, SiO₂, but the inventive concepts are not limited thereto.

Next, the first interlayer insulation layer 80 is planarized. In detail, a top portion of the first interlayer insulation layer 80 is planarized until top surfaces of the first spacer 52 and the second spacer (62 of FIG. 10) are exposed. Here, the planarizing may be performed until a width of the top surface of the second spacer (62 of FIG. 10) becomes equal to a first width W1, as shown in FIG. 11. Meanwhile, the first etch stopping layer 70 formed on the first and second gate structures 20-1 and 20-2, the passivation layer 40 and a portion of the capping layer (29 of FIG. 7) may also be removed by the above planarizing process.

Next, of the first spacer 52 and the second spacer (62 of FIG. 10) having top portions removed, the second spacer (62 of FIG. 10) is selectively etched. As described above, because the first spacer 52 and the second spacer (62 of FIG. 10) include different materials, only the second spacer (62 of FIG. 10) can be selectively etched using etching selectivity between the first spacer 52 and the second spacer (62 of FIG. 10).

Next, referring to FIG. 3, a second interlayer insulation layer 90 is formed on the first interlayer insulation layer 80. Here, the second interlayer insulation layer 90 may be formed by a method which has poor step coverage. Accordingly, the airgap spacer 64 may be formed at opposite sides of the second gate structure 20-2, as shown in FIG. 3. Next, a contact 92 making contact with the first source/drain 42 and the second source/drain 44 while passing through the first and second interlayer insulation layers 80 and 90 is formed.

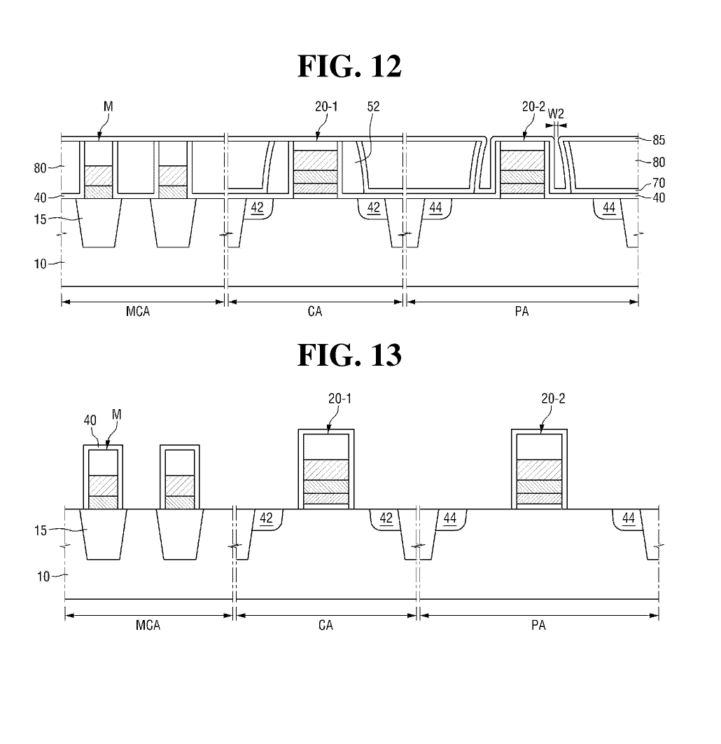

Next, a method for fabricating a memory device according to other example embodiments of the inventive concepts will be described with reference to FIGS. 4 and 12.

FIG. 12 illustrates an intermediate process step for explaining a method for fabricating a memory device according to other example embodiments of the inventive concepts.

Hereinafter, substantially the same contents as those of the previous example embodiments may be omitted and the following description will focus on differences between the present and previous example embodiments.

Referring to FIG. 12, in the present example embodiments, after the process described above with reference to FIG. 11 is completed, a second insulation layer 85 is further formed on the first interlayer insulation layer 80. Here, the second insulation layer 85 may be formed by, for example, atomic layer deposition (ALD).

As shown in FIG. 12, the thus formed second insulation layer 85 may be formed to extend along a top surface of the first interlayer insulation layer 80 and may also be formed on the passivation layer 40 and the first etch stopping layer 70. Accordingly, a width of the second insulation layer 85 disposed on the second gate structure 20-2 may be a second width W2, as shown in FIG. 12. The second width W2 may be smaller than the first width (W1 of FIG. 11) of the previous example embodiments. Accordingly, when the second interlayer insulation layer 90 is formed on the second insulation layer 85, the airgap spacer 65 may be formed more efficiently.

Next, a method for fabricating a memory device according to still example embodiments of the inventive concepts will be described with reference to FIGS. 5, 13 and 14.

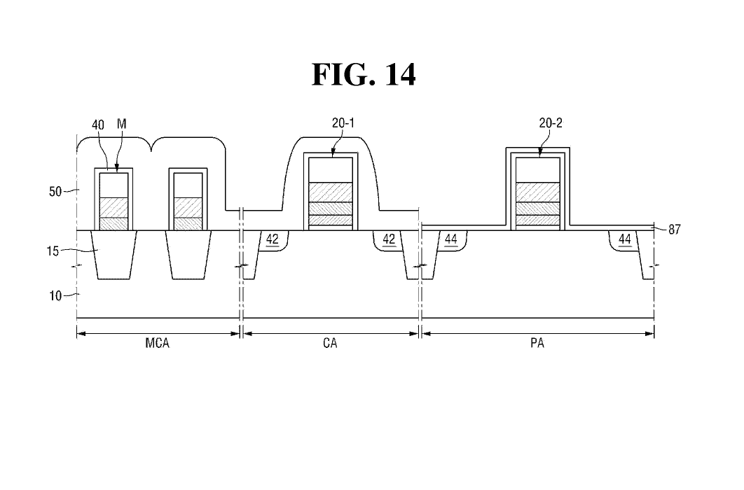

FIGS. 13 and 14 illustrate intermediate process steps for explaining a method for fabricating a memory device according to still example embodiments of the inventive concepts.

Hereinafter, substantially the same contents as those of the previous example embodiments may be omitted and the following description will focus on differences between the present and previous example embodiments.

First, referring to FIG. 13, in the present example embodiments, after the process for forming the passivation layer 40 described above with reference to FIG. 7 is completed, the passivation layer 40 disposed on the top surface of the substrate 10 is completely removed. Next, first and second source/drain 42 and 44 are formed on the exposed top surface of the substrate 10 by, for example, an implantation process. That is to say, in the present example embodiments, impurity may be implanted into the exposed top surface of the substrate 10, rather than being transmitted through the passivation layer 40, thereby forming the first and second source/drain 42 and 44 in the substrate 10.

Next, referring to FIG. 14, a first insulation layer 50 is selectively formed on the MCA and CA. Because the process of forming the first insulation layer 50 is substantially the same as the process described above with reference to FIG. 8, a repeated explanation thereof will be omitted. In addition, a second etch stopper layer 87 is formed on the PA, as shown in FIG. 14. The second etch stopper layer 87 may be formed such that it makes contact with a top surface of the substrate 10, as shown in FIG. 14. The second etch stopper layer 87 may protect the second source/drain 44 formed on the substrate 10 in the course of performing the process shown in FIG. 10 (for example, the processes for forming the first and second spacers 52 and 62). The following processes are substantially the same as described above through the previous example embodiments, and detailed descriptions thereof will be omitted.

While only the method for fabricating the memory device 3 shown in FIG. 5 has been described herein, the method for fabricating the memory device 4 shown in FIG. 6 may be readily analogized by one skilled in the art based on the description having been made hitherto, and a repeated explanation thereof will be omitted.

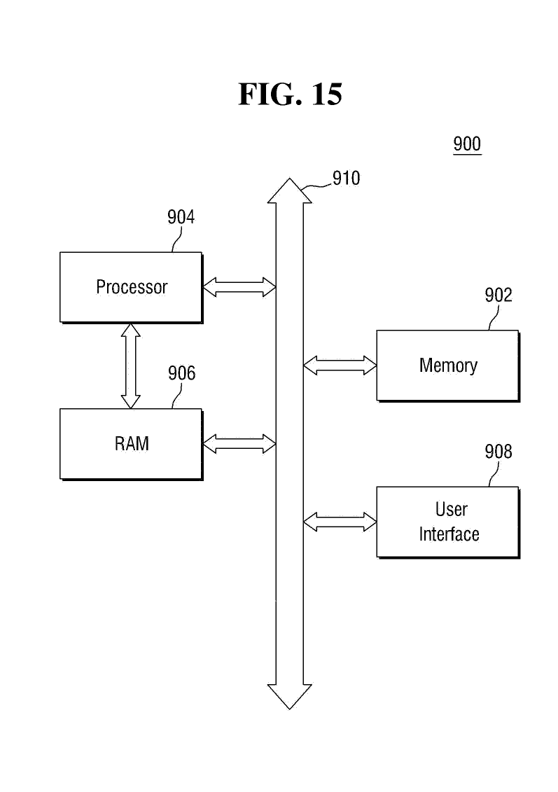

Next, an electronic system to which memory devices according to example embodiments of the inventive concepts can be employed will be described with reference to FIG. 15.

FIG. 15 is a block diagram of an electronic system to which memory devices according to example embodiments of the inventive concepts can be employed.

Referring to FIG. 15, an electronic system 900 may include a memory system 902, a processor 904, a RAM 906, and a user interface 908.

The memory system 902, the processor 904, the RAM 906, and the user interface 908 may perform data communication with each other using a bus 910.

The processor 904 may execute a program and control the electronic system 900. The processor 904 may include at least one selected from the group consisting of a microprocessor, digital signal processor, and logic elements capable of performing functions similar to those of these elements.

The RAM 906 may be used as an operating memory of the processor 904. For example, the RAM 906 may include a volatile memory such as DRAM. In this case, the above-describe memory devices 1 to 4 may be employed as the RAM 906. Meanwhile, the processor 904 and the RAM 906 may be packaged into a semiconductor device or a semiconductor package.

The user interface 908 may be used to input/output data to/from the electronic system 900. The memory system 902 may include, for example, a key pad, a key board, an image sensor, a display device, and so on.

The memory system 902 may store codes for the operation of the processor 904, the data processed by the processor 904 or externally input data. The memory system 902 may include a separate controller for driving the same, and may further include an error correction block. The error correction block may be configured to detect and correct an error of the data stored in the memory system 902 using an error correction code (ECC).

Meanwhile, in an information processing system, such as a mobile device or a desk top computer, a flash memory may be mounted as the memory system 902. For example, the memory system 902 may be configured to be applied to SSD. In this case, the electronic system 900 can stably and reliably store high capacity data in the flash memory.

In some example embodiments, the memory system 902 can be integrated into one semiconductor device to constitute a memory card. For example, the memory system 902 can be integrated into one semiconductor device to constitute a memory card such as a personal computer memory card international association (PCMCIA) card, a compact flash (CF) card, a smart media card, a memory stick, a multimedia card (e.g., MMC, RS-MMC and MMC-micro), a secure digital (SD) card (e.g., SD, mini-SD, micro-SD and SDHC), or a universal flash storage (UFS) card.

The electronic system 900 shown in FIG. 15 can be applied to electronic controllers of various electronic devices.

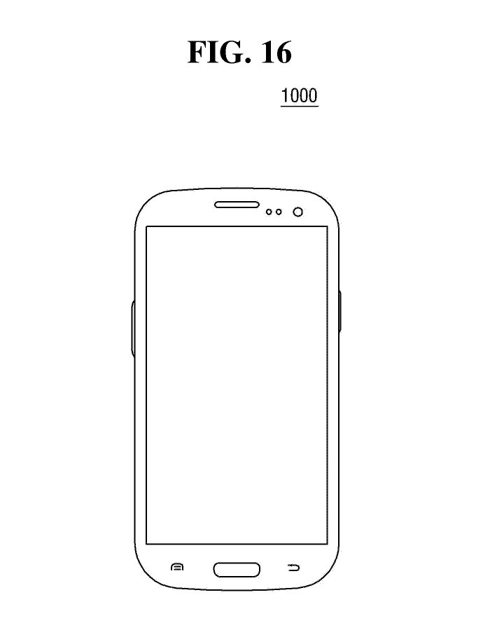

FIG. 16 illustrates an example electronic system used for a smart phone.

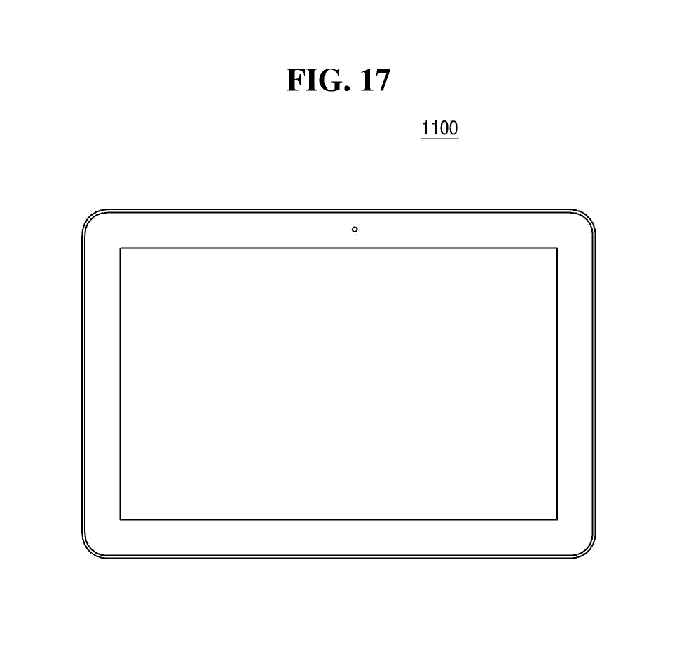

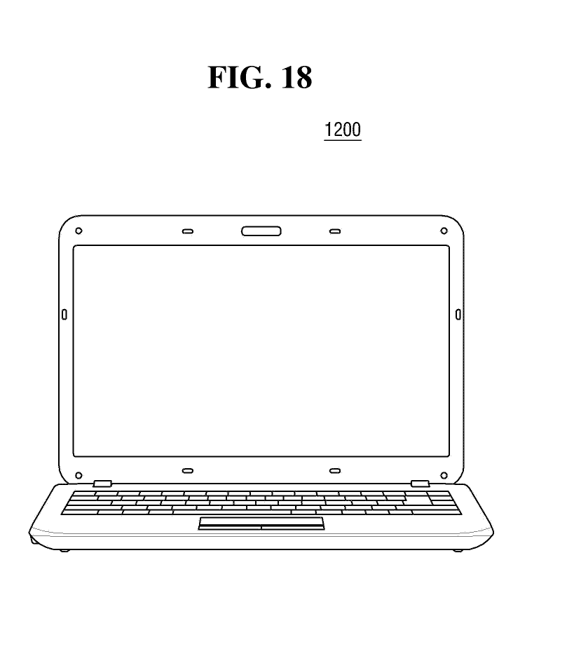

As shown in FIG. 16, in a case where the electronic system (900 of FIG. 15) is used for a smart phone 1000, the electronic system (900 of FIG. 15) may be, for example, an application processor (AP). FIG. 17 illustrates an exemplary electronic system applied to a tablet PC (1100) and FIG. 18 illustrates an exemplary electronic system applied to a notebook computer.

In various example embodiments, the memory system (900 of FIG. 15) can be incorporated into a variety of different types of devices, such as computers, ultra mobile personal computers (UMPCs), work stations, net-books, personal digital assistants (PDAs), portable computers, web tablets, wireless phones, mobile phones, smart phones, e-books, portable multimedia players (PMPs), portable game consoles, navigation devices, black boxes, digital cameras, 3-dimensional televisions, digital audio recorders, digital audio players, digital video recorders, digital video players, devices capable of transmitting/receiving information in wireless environments, one of various electronic devices constituting a home network, one of various electronic devices constituting a computer network, one of various electronic devices constituting a telematics network, RFID devices, or computing systems.

Meanwhile, in a case where the electronic device (900 of FIG. 15) is capable of performing wireless communication, it may use a communication interface protocol for third generation communication systems, e.g., Code Division Multiple Access (CDMA), Global System for Mobile Communications (GSM), North American Digital Cellular (NADC), Extended-Time Division Multiple Access (E-TDMA), Wideband Code Division Multiple Access (WCDMA), and CDMA2000.

While the inventive concepts has been particularly shown and described with reference to example embodiments thereof, it will be understood by those of ordinary skill in the art that various changes in form and details may be made therein without departing from the spirit and scope of the inventive concepts as defined by the following claims. It is therefore desired that the example present embodiments be considered in all respects as illustrative and not restrictive, reference being made to the appended claims rather than the foregoing description to indicate the scope of the inventive concepts.

What is claimed is:

1. A memory device, comprising:
a memory element on a substrate; and
first and second transistors on the substrate,
wherein the first transistor includes a first source/drain, a first gate structure spaced apart from the first source/drain by a first distance, and a spacer on at least one side of the first gate structure and filled with an insulating material,
the second transistor includes a second source/drain, a second gate structure spaced apart from the second source/drain by a second distance, and a spacer filled with air and on at least one side of the second gate structure, and
the second distance is different than the first distance.

2. The memory device of claim 1, wherein the second distance is greater than the first distance.

3. The memory device of claim 1, further comprising:
a passivation layer preventing the first and second gate structures from being oxidized; and
a first etch stopper layer on the spacer filled with the insulating material and the spacer filled with air,
wherein the passivation layer is at one side of the spacer filled with air and the first etch stopping layer is at the other side of the spacer filled with air.

4. The memory device of claim 3, wherein the passivation layer contacts the substrate.

5. The memory device of claim 3, further comprising:
an insulation layer on the passivation layer and the first etch stopping layer,
wherein the spacer filled with air is surrounded by the insulation layer.

6. The memory device of claim 3, further comprising:
a second etch stopper layer contacting the substrate and on the one side of the spacer filled with air.

7. The memory device of claim 6, further comprising:
an insulation layer on the passivation layer and the second etch stopper layer,
wherein the spacer filled with air is surrounded by the insulation layer.

8. The memory device of claim 1, wherein the first gate structure and the second gate structure include a same material.

9. The memory device of claim 1, wherein
the first transistor is on a core area having a sense amplifier configured to read data stored in the memory element, and
the second transistor is on a peripheral area having an input/output (I/O) circuit configured to output the data read by the sense amplifier to an area external to the memory device.

10. The memory device of claim 1, wherein the memory element includes a dynamic random access memory (DRAM).

11. A memory device, comprising:
a substrate including first to third regions;
a memory element on the first region;
a first transistor on the second region closer to the first region than to the third region and including a spacer filled with an insulating material; and
a second transistor on the third region and including a spacer filled with air.

12. The memory device of claim 11, wherein the first region includes a memory cell array area, the second region includes a core area, and the third region includes a peripheral area.

13. The memory device of claim 12, wherein the memory cell array area includes a DRAM element, the core area includes a sense amplifier configured to read data stored in the DRAM element, and the peripheral area includes an input/output (I/O) circuit configured to output the data read by the sense amplifier to the outside.

14. The memory device of claim 11, wherein
the first transistor further includes a first source/drain and a first gate structure apart from the first source/drain by a first distance, and
the second transistor includes a second source/drain and a second gate structure apart from the second source/drain by a second distance.

15. The memory device of claim 14, wherein the second distance is greater than the first distance.

16. A nonvolatile memory device, comprising:
a memory element in a memory cell region of a substrate;
a first transistor in a core region of the substrate and including a first gate structure having first sidewalls each respectively insulated by an insulative material; and
a second transistor in a peripheral region of the substrate and including a second gate structure having second sidewalls each respectively insulated by a cavity filled with air,
wherein the core region is closer to the memory cell region than the peripheral region is to the memory cell region.

17. The nonvolatile memory device of claim 16, wherein
the insulative material is in the form of a spacer, and
the cavity filled with air is defined by an etch stop layer and a passivation layer.

18. The nonvolatile memory device of claim 17, wherein
the first transistor is over a first source/drain region, and the first gate structure is spaced apart from the first source/drain region by a first distance equal to or less than a width of the spacer, and
the second transistor is over a second source/drain region, and the second gate structure is spaced apart from the second source/drain region by a second distance greater than a width of the cavity.

19. The nonvolatile memory device of claim 18, wherein the second distance is greater than the first distance.

20. The nonvolatile memory device of claim 16, wherein
the insulative material is in the form of a spacer, and
the cavity filled with air is defined by an insulation layer, an etch stop layer and a passivation layer.
